(19) United States
(12) Patent Application Publication
(10) Pub. No.: US 2025/0216418 A1
(43) Pub. Date: Jul. 3, 2025

(54) TEST SYSTEM FOR HIGH-VOLTAGE AND HIGH-CURRENT TESTING ON A PLURALITY OF POWER SEMICONDUCTOR DEVICES COMPRISED IN A WAFER, AND CONTACTING SYSTEM

(71) Applicant: CREA COLLAUDI ELETTRONICI AUTOMATIZZATI S.R.L., Cirie' (Torino) (IT)

(72) Inventors: Marco MARCINNO', Cirie' (Torino) (IT); Carlo CIANFEROTTI, Piombino (Livorno) (IT)

(21) Appl. No.: 18/852,539

(22) PCT Filed: Mar. 30, 2023
(86) PCT No.: PCT/IB2023/053180

§ 371 Date: Sep. 30, 2024

(30) Foreign Application Priority Data
Mar. 31, 2022 (IT) 102022000006356

(51) Int. Cl. G01R 1/067; G01R 1/073; G01R 31/26

(52) U.S. Cl. CPC G01R 1/06777; G01R 1/07342; G01R 31/2607; G01R 1/0675

(57) ABSTRACT

A test system for high-voltage and high-current testing of power semiconductor devices comprised in a wafer which has a test machine, a needle probe card and a contacting system is provided. The contacting system has a wafer housing conductive portion and a test electrical circuit closing contact conductive portion. The test electrical circuit closing contact conductive portion has a shape and an extension to determine respective straight and continuous current conduction paths from each power semiconductor device to at least one test electrical circuit closing terminal arranged along a predetermined non-variable direction. Each current conduction path extends along a direction parallel to or coincident with the predetermined non-variable direction. A contacting system is also provided.

### TECHNICAL FIELD

The present invention is generally in the field of high-voltage and high-current testing on a plurality of power semiconductor devices comprised in a wafer; in particular, the invention relates to a test system for high-voltage and high-current testing on a plurality of power semiconductor devices comprised in a wafer, particularly for testing the dynamic parameters of such semiconductor devices. The invention also relates to a contacting system for use in such a test system.

### PRIOR ART

In the field of semiconductor devices, the practice is to perform tests on electronic devices before their appropriate packaging on a substrate or chip and their sale for electrical/electronic applications.

Tests performed on semiconductor devices for static parameters of the same device and tests performed on semiconductor devices for dynamic parameters are currently known.

The two tests described above are normally carried out at different times in the fabrication of a semiconductor device.

In particular, tests for static parameters are carried out under direct current.

In contrast, in tests for dynamic parameters, alternating electronic signals, for example having state switching or polarity reversals, are applied to the semiconductor devices.

In the tests for the evaluation and/or verification of dynamic parameters in which switching is present, the issue of parasitic inductances emerges. In fact, parasitic inductances during signal switching may cause overvoltages that may damage both the test machine and the semiconductor device under test.

As a result, tests for evaluating dynamic parameters are very difficult to perform, especially those for verifying and/or evaluating the actual operation of the device under test, especially at an early stage of the fabrication/production process.

Moreover, tests for evaluating and/or verifying dynamic parameters are even more complex when performed on power semiconductor devices. For power semiconductor devices, the tests are conducted at high voltages and high currents; therefore, the powers involved are very high.

It follows that even in the presence of very small parasitic inductances, the overvoltages caused by these parasitic inductances during high-voltage and high-current testing would cause irreparable damage to the power semiconductor device under test.

Several functional tests on semiconductor electronic devices, in particular power devices, are known and referred to in the industry by the acronyms RBSOA, FBSOA, and SCSOA, in which voltages of the order of kVolts and currents of hundreds of amperes, up to several thousand amperes kA, are envisaged to be used to perform such functional tests.

There is an increasing demand from manufacturers of power semiconductor devices to be able to detect possible malfunctions in power semiconductor devices as early as possible in the fabrication process thereof. The demand in particular to be able to perform tests on such power semiconductor devices when they are still in an early stage of the fabrication process is increasingly significant, ideally attempting to carry out testing directly on the semiconductor wafer on which a plurality of devices has been fabricated as known to a person skilled in the art.

In the prior art, there are no known test machines/systems capable of performing high-voltage and high-current testing on power electronic devices while said devices are still incorporated in the wafer with other electronic devices, in particular for performing tests for evaluating and/or verifying the dynamic parameters of power electronic devices before they have been separated individually.

Contacting systems for test machines that are equipped with a contacting disk and a test electrical circuit closing conductive plate are known in the field, particularly for static testing. In such known contacting systems, the contacting disk is only electrically connected to the test electrical circuit closing conductive plate by means of flexible electrical wiring, which freely extends between the contacting disk and the test electrical circuit closing conductive plate.

However, the use of such electrical wiring for connecting the contacting disk and the test electrical circuit closing conductive makes the contacting system unsuitable for use in high-voltage and high-current testing of a plurality of power semiconductor devices, particularly for testing dynamic parameters.

The use of such electrical wiring leads to a high parasitic inductance being generated during the testing of dynamic parametrics.

At present, the most modern power semiconductor devices are designed to be faster in terms of switching times. A fast switching time advantageously reduces energy dissipation. In light of their fast switching times, these semiconductor devices should therefore be tested with faster switching.

Disadvantageously, because the known contacting systems just described generate high parasitic inductance during testing of dynamic parametrics, they may not be used for this type of testing.

In fact, if the parasitic inductance is high, it will not be possible to provide power to the power semiconductor device and it will not be possible to test the power semiconductor device at the desired switching speed.

### SUMMARY OF THE INVENTION

One object of the present invention is to provide a test system and a contacting system for use in such a test system that enable high-voltage and high-current tests to be performed on a plurality of power semiconductor devices comprised in a wafer, particularly dynamic high-voltage and high-current tests.

A further object of the present invention is to provide a test system and a contacting system for use in such a test system that make it possible to perform dynamic high-voltage and high-current tests even at high desired switching speeds.

The aforesaid and other objects and advantages are achieved, according to a first aspect of the invention, by a test system for high-voltage and high-current testing on a plurality of power semiconductor devices comprised in a wafer having the features defined in claim 1 and, according to a further aspect of the invention, by a contacting system having the features defined in claim 15. Preferred embodiments of the invention are defined in the dependent claims, the content of which is to be understood as an integral part of the present description.

### BRIEF DESCRIPTION OF THE DRAWINGS

The functional and structural features of some preferred embodiments of a system for high-voltage and high-current testing on a plurality of power semiconductor devices comprised in a wafer and a contacting system according to the invention will now be described. Reference is made to the accompanying drawings, wherein:

FIG. 1 shows an exemplary external structure of a test system for high-voltage and high-current testing of a plurality of power semiconductor devices comprised in a wafer;

FIG. 2 shows an exemplary embodiment of a contacting system for a test system according to the present invention;

FIG. 3 is an exploded view of a contacting system in which the test electrical circuit closing contact conductive portion and the wafer housing conductive portion are two distinct elements;

FIG. 4 shows an exemplary embodiment of a handling system according to the present invention;

FIG. 5a shows an exemplary needle probe card;

FIG. 5b shows an exemplary needle probe card when connected to a test electrical circuit closing terminal;

FIG. 5c shows the needle probe card in FIG. 5b when the contacting system is brought into contact with the test electrical circuit closing terminal;

FIG. 6 is an example of a possible movement of a contacting system performed by a handling system according to the present invention.

### DETAILED DESCRIPTION

Before explaining in detail a plurality of embodiments of the invention, it should be clarified that the invention is not limited in its application to the design details and configuration of the components presented in the following description or illustrated in the drawings. The invention may assume other embodiments and be implemented or constructed in practice in different ways. It should also be understood that the phraseology and terminology have a descriptive purpose and should not be construed as limiting. The use of “include” and “comprise” and the variations thereof are intended to cover the elements set out below and the equivalents thereof, as well as additional elements and the equivalents thereof.

The following describes embodiments of a test system for high-voltage and high-current testing on a plurality of power semiconductor devices comprised in a wafer, particularly for high-voltage and high-current dynamic testing.

In one embodiment, the test system 100 comprises a test machine arranged to perform a predetermined high-voltage and high-current test function on said plurality of power semiconductor devices.

For example, the predetermined test function may perform tests known by the acronyms RBSOA, FBSOA and SCSOA, etc., among others.

The electrical current supplied to the power semiconductor device under test may, for example, be determined by the predetermined high-voltage, high-current test function performed by the test machine.

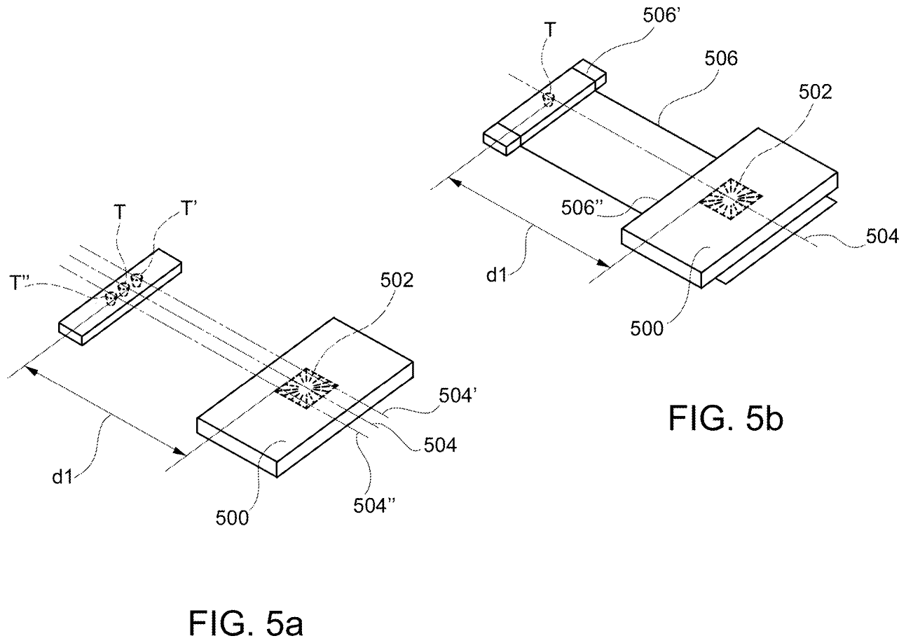

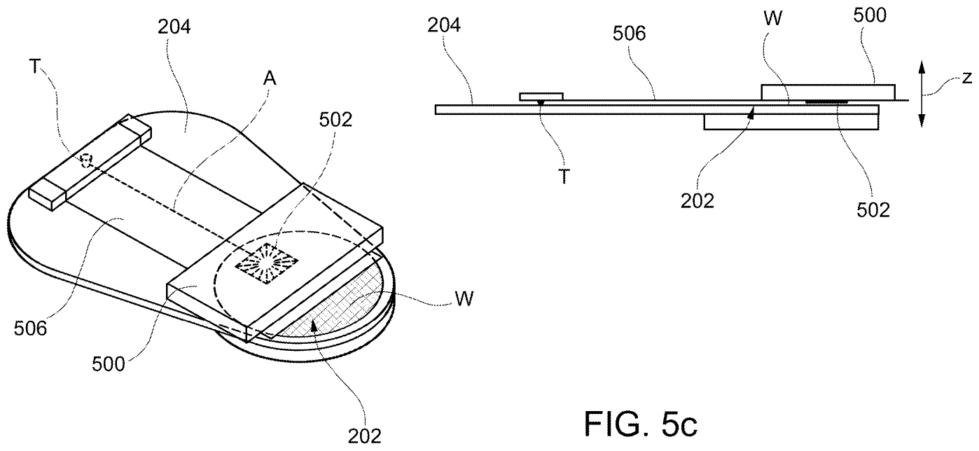

The test system 100 further comprises a needle probe card 500 arranged to be connected to such a test machine. The needle probe card 500 comprises a plurality of needles 502 suitable for being placed in contact with at least one power semiconductor device under test at a time of said plurality of power semiconductor devices comprised in the wafer W. Each needle is suitable for allowing an electrical current to flow through the at least one power semiconductor device under test. An exemplary needle probe card 500 is shown in FIG. 5a.

For example, at least one at a time, all of the power semiconductor devices of the wafer W arranged on said wafer housing conductive portion 202 may be placed in contact with said plurality of needles 502 so as to be under test.

For example, during the performance of a test, the plurality of needles 502 (or at least part of the plurality of needles) may contact only one power semiconductor device at a time, or the plurality of needles 502 (or at least part of the plurality of needles) may simultaneously contact one subset of power semiconductor devices of said plurality of overall power semiconductor devices at a time.

For example, in the field of testing for power semiconductor devices, a needle probe card 500 may contact a plurality of needles 502, wherein a current may flow on the emitter or anode of at least one power semiconductor device under test. A needle probe card 500 may comprise a large number of needles 502 in order to be able to apply a very high current on a power semiconductor device while being able to exploit the largest possible area of the semiconductor device in order to reduce the current density per unit area of the device and to divide the current over several needles. A needle probe card 500 may also comprise an intrinsic safety system that may monitor the current entering the probe card. If the total input current to the needle probe card 500 exceeds a predetermined direct current value, this safety system may be able to interrupt the input current to the needle probe card 500. A needle probe 500 may also be coupled to/associated with an appropriate safety system, such as that described in international patent application WO2021240431, the proprietor thereof being the same as that of the present patent application.

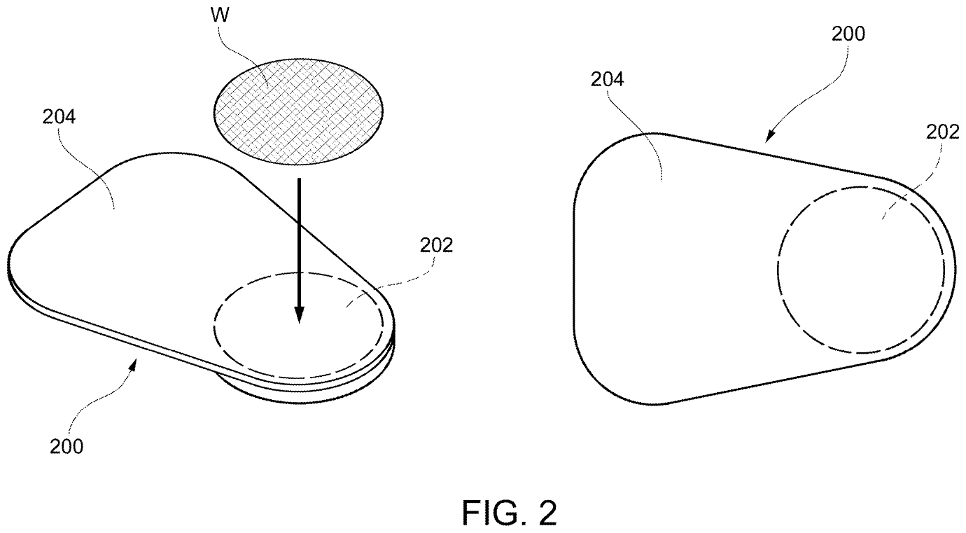

The test system further comprises a contacting system 200. A contacting system 200 is illustrated by way of example in FIG. 2. The left side of FIG. 2 illustrates a perspective view of the contacting system 200, while the right side illustrates a top view of the same contacting system 200.

The contacting system 200 comprises a wafer housing conductive portion 202 and a test electrical circuit closing contact conductive portion 204.

The wafer housing conductive portion 202 is provided for housing the wafer W to be contacted by the plurality of needles 502 of the needle probe card 500 during testing.

For example, the wafer housing conductive portion 202 may extend along a predetermined support plane.

The test electrical circuit closing contact conductive portion 204 is electrically connected to the wafer housing conductive portion 202.

The test system 100 further comprises at least one test electrical circuit closing terminal T.

As, for example, observable in FIG. 5a, this at least one test electrical circuit closing terminal T is arranged along a predetermined non-variable direction 504 and at a predetermined nonvariable distance dl from the plurality of needles 502 of the needle probe card 500.

Preferably, as may also be observed in FIG. 5a, there may also be a plurality of test electrical circuit closing terminals T, T′, T″ arranged along respective predetermined directions 504, 504′, 504″.

For example, the at least one test electrical circuit closing terminal T may comprise one or more pogo-pins.

In use, the at least one test electrical circuit closing terminal T is arranged to be brought into contact with the test electrical circuit closing contact conductive portion 204 of the contacting system 200.

The at least one test electrical circuit closing terminal T is coupled to the test machine by means of a conductive path 506 arranged along said predetermined non-variable direction 504.

For example, as explained in detail in the following description, the at least one test electrical circuit closing terminal T may be coupled directly to the test machine by means of the conductive path 506 or may be coupled indirectly to the test machine by means of the needle probe card. In the second case, the at least one test electrical circuit closing terminal T may be connected to the needle probe card by means of the conductive path 506, and the needle probe card may in turn be connected to the test machine.

At least part of the conductive path 506 facing the test electrical circuit closing contact conductive portion 204 is straight and parallel to the test electrical circuit closing contact conductive portion 204 of the contacting system 200.

For example, preferably, the part of the conductive path 506 facing the test electrical circuit closing contact portion 204 may be at a distance from the conductive portion between a fraction of a millimeter and several millimeters.

The test electrical circuit closing contact conductive portion 204 of the contacting system 200 has such a shape and extension that it determines respective straight and continuous current conduction paths A from each power semiconductor device to at least one test electrical circuit closing terminal T.

Each current conduction path A extends along a direction parallel to or coincident with said predetermined non-variable direction 504.

In other words, each straight current conduction path A may extend along a direction parallel to or coincident with the predetermined non-variable direction 504 along which the test electrical circuit closing terminal T that is coupled to the test machine via the conductive path 506 is arranged.

Advantageously, since 1) a portion of the conductive path 506 facing the test electrical circuit closing contact portion 204 is straight and parallel to the test electrical circuit closing contact conductive portion 204 of the contacting system and 2) the current conduction paths A are straight and extend along a direction parallel to or coincident with said predetermined non-variable direction 506 over which the conductive path 506 in which the electrical current flows is arranged, the parasitic inductances are compensated for and are kept at a low level such that dynamic tests may be performed even on power semiconductor devices.

As is well known in the field, the inductance increases as the area between the conductors increases. Since the current conduction paths A and the conductive path 506 are parallel to each other, the area between the conductors is reduced, resulting in a reduction of the parasitic inductance.

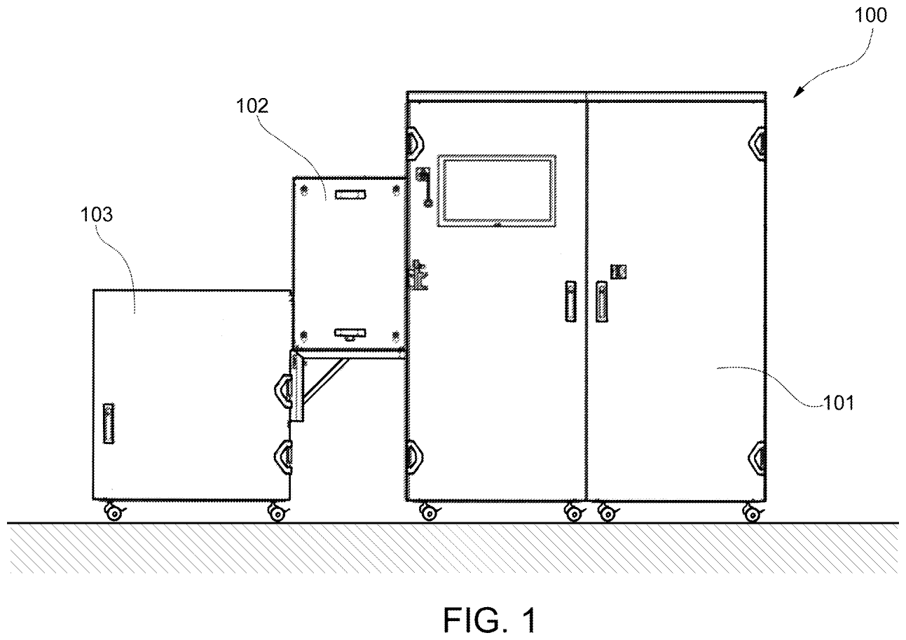

In FIG. 1, a possible external structure of the test system 100 just described is illustrated by way of example. This structure may comprise external enclosures that may contain the elements of the test system. For example, the block 101 (“test machine”) may contain the test machine, and the block 103 (“chuck handler”) may include the contacting system, the test electrical circuit closing terminal, and the needle probe card. Between the block 101 and the block 102, the block 102 (“probe card interface”) may also be provided, which may include a needle probe card interface module. For example, the block 102 may be associated with or included in the block 101.

Preferably, the contacting system 200 may be arranged to:
a) receive an electrical current output from said at least one power semiconductor device under test; or
b) convey an electrical current to be supplied as input to said at least one power semiconductor device under test.

In case a), the test electrical circuit closing terminal T may be arranged to receive said electrical current flowing into said contacting system.

In case b), the test electrical circuit closing terminal T may be arranged to supply the electrical current to the contacting system 200.

In other words, when a power semiconductor device is placed under test, the electrical current entering or exiting it will be allowed to flow in the test electrical circuit closing contact conductive portion 204 of the contacting system 200 toward the test electrical circuit closing terminal T along a relevant straight and continuous current conduction path A.

The fact that the electrical current entering or exiting a power semiconductor device under test may flow in the test electrical circuit closing contact conductive portion 204 of the contacting system 200 toward the test electrical circuit closing terminal T along a relevant straight current conduction path A may occur for each power semiconductor device.

Preferably, as may be observed in FIG. 5b, a first end 506′ of the conductive path 506 may be arranged to be connected to the at least one test electrical circuit closing terminal T. A second end 506″ of the conductive path 506, opposite to the first end, may be arranged to be connected to the needle probe card 500 that is connected to the test machine. FIG. 5c shows the needle probe card 500 shown by way of example in FIG. 5b, when the contacting system 200 is brought into contact with the test electrical circuit closing terminal T. The left side of the FIG. 5c shows a perspective view of the contacting system and the needle probe card, while the right side of FIG. 5c shows a side view of the contacting system and the needle probe card.

In an alternative not shown in the figures, a first end of the conductive path may be arranged to be connected to at least one test electrical circuit closing terminal. A second end of the conductive path, opposite the first end, may be arranged to be connected directly to the test machine.

For either possibility, the conductive path 506 may include one or more electrical cables. For example, all electrical cables may be embedded encapsulated in an insulating sheath. The insulating sheath may be made of a non-deformable material, as the position of the test electrical circuit closing terminal T with respect to the plurality of needles 502 of the needle probe card 500 is not variable.

Preferably, the test electrical circuit closing contact conductive portion 204 and said wafer housing conductive portion 202 may be made in one piece.

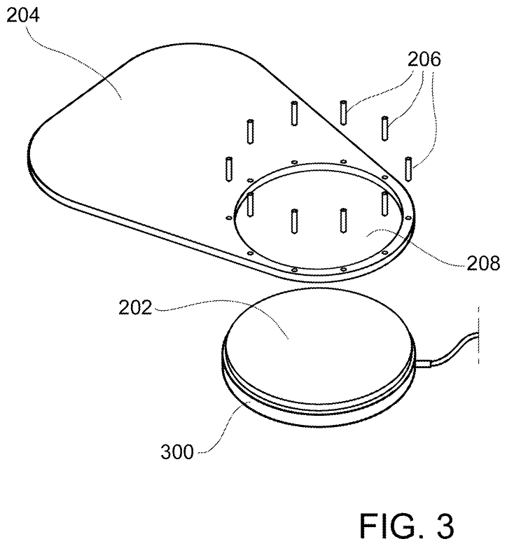

Preferably, as observable in the alternative of FIG. 3, the test electrical circuit closing contact conductive portion 204 and the wafer housing conductive portion 202 of the contracting system 200 may be at least two distinct elements. In such a case, the test electrical circuit closing contact conductive portion 204 may be stably bound in contact with the wafer housing conductive portion 202.

For example, to achieve the stable binding, the test electrical circuit closing contact conductive portion 204 may be stably bound to the wafer housing conductive portion 202 through appropriate coupling or fastening means 206, (e.g., through interlocking means or screws).

Preferably, the test electrical circuit closing contact conductive portion 204 may include a through-hole 208 or a housing arranged to accommodate the wafer housing conductive portion 202.

Preferably, the wafer housing conductive portion 202 may be comprised in a contacting disk 300.

For example, the contacting disk may be of any type already known in the field. In general, a contacting disk is usually provided for housing the wafer to be tested.

For example, but not necessarily, the wafer housing conductive portion 202 (e.g., the contacting disk) may be provided with suction holes, for example connected to a pump. The air drawn in by the pump through the suction holes may be used to hold the wafer in a predetermined position during testing. In fact, any displacement of the wafer W during the test could cause damage to the wafer and the test machine with which the test is performed. For example, the suction holes may be made in the support surface of the wafer housing conductive portion 202. Drawing the wafer W to the wafer housing conductive portion 202 may also reduce the contact resistance.

For example, a heating system may be associated with the wafer housing conductive portion 202. Such a heating system may be arranged to heat the wafer housing conductive portion 202. For example, the heating system may bring the wafer to a temperature of substantially 175° C., since dynamic tests are usually carried out at that temperature (i.e., junction temperature indicated by the datasheets of the power semiconductor devices).

Preferably, the test electrical circuit closing contact conductive portion 204 and the wafer housing conductive portion 202 may be arranged on respective planes parallel to each other or may both be arranged on a single plane (e.g., coinciding with the wafer housing plane 202).

Preferably, as may be seen, for example, in FIGS. 2 and 3, the contacting system 200 may generally have a triangular shape. The one or more vertices of the triangle may be rounded. The wafer housing conductive portion 202 of the contacting system 200 may be arranged at one of said vertices of the triangle.

In an exemplary embodiment, the contacting system 200 may have an isosceles triangle shape with rounded vertices. In this case, the wafer housing conductive portion 202 may be arranged at the vertex of the triangle that is opposite the base of the triangle.

Clearly, in different embodiments, the shape of the contacting system 200 could also be different, e.g., rectangular or square.

Preferably, the test electrical circuit closing contact conductive portion 204 may be made of the same conductive material as the wafer housing conductive portion 202. The test electrical circuit closing contact conductive portion 204 may have a thickness in the range of several millimeters.

Preferably, the test system 100 may comprise a handling system 400 arranged to move the contacting system so that, at least one at a time, all of the power semiconductor devices of the wafer W arranged on said wafer housing conductive portion 202 are placed in contact with said plurality of needles 502 so as to be under test.

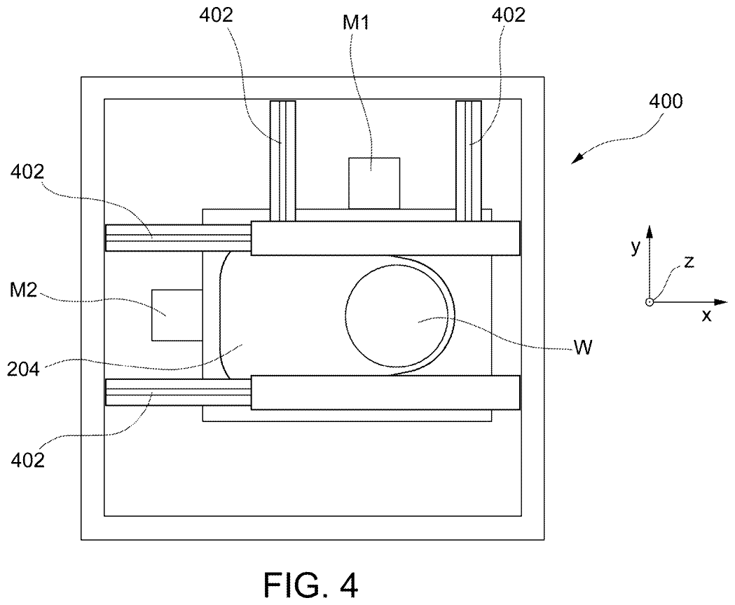

An exemplary embodiment of a handling system is shown in FIG. 4.

The handling being carried out in such a way that, at any position into which said contacting system 200 is moved by the handling system 400, the at least one test electrical circuit closing terminal T is arranged to contact the test electrical circuit closing contact conductive portion 204 of the contacting system 200.

For example, for moving the contacting system 200, appropriate guides 402 may be provided, and the movement may be generated from one or more electrical motors M1, M2.

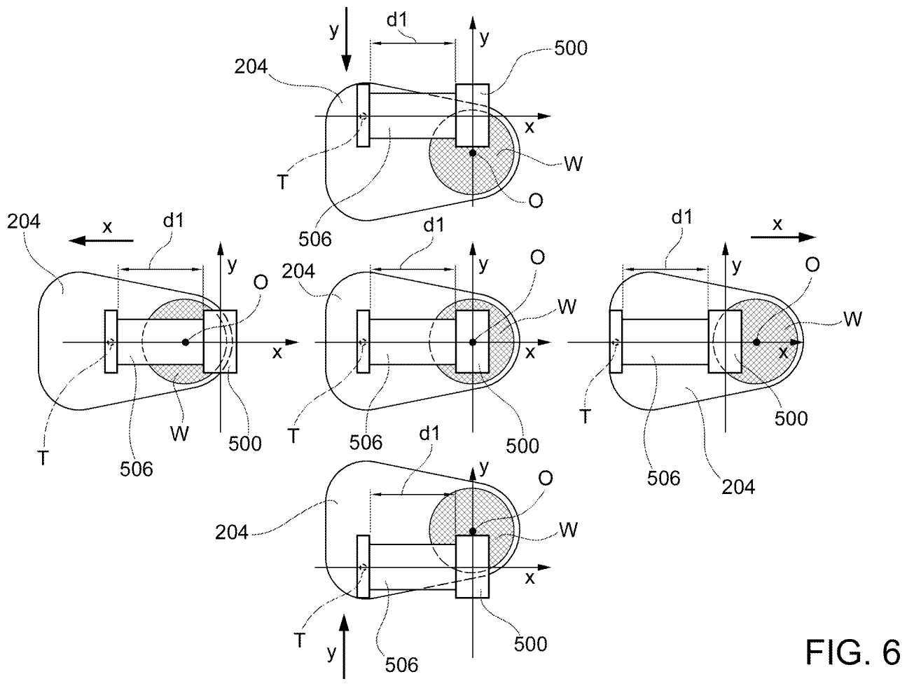

Preferably, as may be observed in FIGS. 5c and 6, the handling system may be arranged to move the contacting system according to three movement directions x, y, z orthogonal to each other.

In particular, FIG. 5c shows the direction z along which the contacting system may move. FIG. 6 shows the movement directions x and y along which the contacting system may move.

For example, the center of FIG. 6 shows the case where the center O of the wafer housing conductive portion 202 of the contacting system is brought to the intersection point of the movement directions x and y. The right side of FIG. 6 shows the case where the contacting system is shifted according to the positive sense of the movement direction x relative to the intersection point of the movement directions x and y. The left side of FIG. 6 shows the case where the contacting system is shifted according to the negative sense of the movement direction x relative to the intersection point of the movement directions x and y. The top part of FIG. 6 shows the case where the contacting system is shifted according to the negative sense of the movement direction y relative to the intersection point of the movement directions x and y. The bottom part of FIG. 6 shows the case where the contacting system is shifted according to the positive sense of the movement direction y relative to the intersection point of the movement directions x and y. Clearly, in FIG. 6, the position of the needle probe card 500, the test electrical circuit closing terminal T and the conductive path 506 is not varied in any of the 4 movement examples shown.

Preferably, the handling system 400 may be arranged to move the contacting system 200 according to a pre-established path.

Preferably, the pre-established path may be stored in an appropriate storage medium associated with, or included in, said test system 100.

For example, the storage medium may be a memory, e.g.:
a non-volatile memory, i.e., a memory capable of retaining information in memory even in the absence of power (examples of non-volatile memory may be ROM, flash memory, a large proportion of magnetic memories, etc.); and
a volatile memory (temporary memory), which, unlike non-volatile memories, requires continuous power supply in order to keep data stored (examples of non-volatile memory may be RAM [DRAM or SRAM], T-RAM, Z-RAM, and TT-RAM).

For example, the path may be appropriately defined by a user depending on the type of test to be performed or the shape of the wafer W.

Or, the pre-established path may be determined by a predetermined high-voltage, high-current test function performed by said test machine. In other words, the path may be determined automatically by the predetermined wafer map function performed by said test machine.

In a further aspect, the present invention relates to a contacting system 200 for use in a test system 100 according to any of the embodiments described above.

The contacting system comprises:
a wafer housing conductive portion 202; and
a test electrical circuit closing contact conductive portion 204.

The wafer housing conductive portion 204 being provided for housing a wafer W to be contacted by a plurality of needles 502 of a needle probe card 500 during testing.

The test electrical circuit closing contact conductive portion 204 being electrically connected to said wafer housing conductive portion 202.

In use, the test electrical circuit closing contact conductive portion 204 is arranged to be brought into contact with the at least one test electrical circuit closing terminal T of the test system 100, so that the test electrical circuit closing contact conductive portion 204 of the contacting system 200 is parallel to the conductive path 506 of the test system that couples the at least one test electrical circuit closing terminal T of the test system 100 to the test machine of the test system 100.

Thus, the advantage achieved is that of providing a test system and a contacting system for use in such a test system that enable the reduction of parasitic inductance that may be generated when performing high-voltage and high-current tests on a plurality of semiconductor devices comprised in a wafer, particularly dynamic high-voltage and high-current tests, making it possible to implement them even for power semiconductor devices when said devices are still embedded in the wafer among other electronic devices.

An additional advantage is that of providing a solution for testing the power semiconductor device at the desired switching speed.

Various aspects and embodiments of a test system for high-voltage and high-current testing of a plurality of power semiconductor devices comprised in a wafer and of a contacting system have been described according to the invention. It is understood that each embodiment may be combined with any other embodiment. Moreover, the invention is not limited to the embodiments described, but may be varied within the scope defined by the appended claims.

What is claimed is:

1. A test system for high-voltage and high-current testing on a plurality of power semiconductor devices comprised in a wafer, the test system comprising:
a test machine arranged to execute a predetermined high-voltage and high-current test function on said plurality of power semiconductor devices;
a needle probe card arranged to be connected to said test machine;
wherein said needle probe card comprises:
a plurality of needles adapted to be placed in contact with at least one power semiconductor device under test at a time of said plurality of power semiconductor devices comprised in the wafer, each needle being adapted to allow an electrical current to flow through said at least one power semiconductor device under test;
the test system further comprising:
a contacting system comprising a wafer housing conductive portion and a test electrical circuit closing contact conductive portion;
the wafer housing conductive portion being provided for housing the wafer to be contacted via the plurality of needles of the needle probe card during tests;
the test electrical circuit closing contact conductive portion being electrically connected to said wafer housing conductive portion;
the test system further comprising at least one test electrical circuit closing terminal disposed along a predetermined non-variable direction and at a predetermined non-variable distance from said plurality of needles of the needle probe card;
the at least one test electrical circuit closing terminal being arranged to be brought into contact with the test electrical circuit closing contact conductive portion of the contacting system;
the at least one test electrical circuit closing terminal being coupled to the test machine by a conductive path arranged along said predetermined non-variable direction;
a portion of the conductive path facing the test electrical circuit closing contact portion being straight and parallel to the test electrical circuit closing contact conductive portion of the contacting system;
the test electrical circuit closing contact conductive portion of the contacting system having a shape and an extension such that respective straight and continuous current conduction paths are determined from each power semiconductor device to the at least one test electrical circuit closing terminal;
each current conduction path extending along a direction parallel to or coincident with said predetermined non-variable direction.

2. The test system of claim 1, wherein said contacting system is arranged to:
receive an electrical current exiting from said at least one power semiconductor device under test; or
convey an electrical current to be supplied as input to said at least one power semiconductor device under test; and wherein
when said contacting system is arranged to receive the electrical current exiting from said at least one power semiconductor device under test, said at least one test electrical circuit closing terminal is arranged to receive said electrical current flowing into said contacting system;
when said contacting system is arranged to convey the electrical current to be supplied as input to said at least one power semiconductor device under test, said at least one test electrical circuit closing terminal is arranged to supply said electrical current to said contacting system.

3. The test system of claim 1, wherein:
a first end of the conductive path is arranged to be connected to the at least one test electrical circuit closing terminal; and
a second end of the conductive path, opposite said first end, is arranged to be connected to the needle probe card.

4. The test system of claim 1, wherein said test electrical circuit closing contact conductive portion and said wafer housing conductive portion are made in one piece.

5. The test system of claim 1, wherein said test electrical circuit closing contact conductive portion and said wafer housing conductive portion are made of at least two separate elements, and
wherein said test electrical circuit closing contact conductive portion is stably bound in contact with said wafer housing conductive portion.

6. The test system of claim 5, wherein said test electrical circuit closing contact conductive portion includes a through-hole or a housing to accommodate said wafer housing conductive portion.

7. The test system of claim 1, wherein said test electrical circuit closing contact conductive portion and said wafer housing conductive portion are arranged on respective planes parallel to each other or are both arranged on a single plane.

8. The test system of claim 1, wherein said contacting system has a shape of a triangle;
wherein one or more vertices of said triangle are rounded; and
wherein said wafer housing conductive portion of the contacting system is arranged at one of said vertices of the triangle.

9. The test system of claim 1, wherein said test electrical circuit closing contact conductive portion is made of a same conductive material as the wafer housing conductive portion.

10. The test system of claim 1, wherein said wafer housing conductive portion is comprised in a contacting disk.

11. The test system of claim 1, further comprising a handling system arranged to move said contacting system, so that, at least one at a time, all of the power semiconductor devices of the wafer arranged on said wafer housing conductive portion are placed in contact with said plurality of needles so as to be under test;
wherein, at any position into which said contacting system is moved by the handling system, said at least one test electrical circuit closing terminal is arranged in contact with said test electrical circuit closing contact conductive portion of said contacting system.

12. The test system of claim 11, wherein said handling system is arranged to move said contacting system according to three movement directions orthogonal to each other.

13. The test system of claim 11, wherein said handling system is arranged to move said contacting system according to a pre-established path.

14. The test system of claim 13, wherein said pre-established path is stored in a suitable storage means associated with, or comprised in, said test system;
or,
wherein said pre-established path is determined by a predetermined wafer map function performed by said test machine.

15. A contacting system for use in the test system of claim 1, comprising:
a wafer housing conductive portion; and
a test electrical circuit closing contact conductive portion;
the wafer housing conductive portion being provided for housing a wafer to be contacted via a plurality of needles of a needle probe card during tests;
the test electrical circuit closing contact conductive portion being electrically connected to said wafer housing conductive portion;
in use, the test electrical circuit closing contact conductive portion being brought into contact with the at least one test electrical circuit closing terminal of the test system, so that said test electrical circuit closing contact conductive portion of the contacting system is parallel to the conductive path of the test system that couples the at least one test electrical circuit closing terminal of the test system to the test machine of the test system.
